(19) United States
(12) Patent Application Publication
(10) Pub. No.: US 2002/0122993 A1
(43) Pub. Date: Sep. 5, 2002

(54) Stencil reticles for charged-particle-beam microlithography, and fabrication methods for making same

(75) Inventor: Norihiro Katakura, Kawasaki-shi (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/085,209

(22) Filed: Feb. 26, 2002

(30) Foreign Application Priority Data
Mar. 4, 2001 (JP) 2001-104435

(51) Int. Cl. G03F 9/00

(52) U.S. Cl. 430/5

(57) ABSTRACT

Methods are disclosed for fabricating, from a reticle blank, a stencil reticle for use in charged-particle-beam (CPB) microlithography. The methods prevent the accumulation, during a dry-etching step in which stencil apertures corresponding to pattern elements are formed in the membrane of the reticle blank, of dry-etching gas adjacent a back side of the membrane. Removing dry-etching gas from this location prevents the gas from eroding the membrane and, hence, prevents membrane fracture. In the reticle blank, the membrane is supported by a grillage of struts or the like typically made from a silicon substrate. To exhaust the dry-etching gas, a gap can be provided between a major surface of a dry-etching electrode and a second major surface of the reticle blank defined by edges of the grillage. Alternatively, channels can be defined either in the major surface of the dry-etching electrode or by forming notches or the like in the grillage elements.

### FIELD

This disclosure pertains to microlithography (transfer-exposure of a pattern from a reticle to a substrate). Microlithography is a key technique used in the manufacture of microelectronic devices such as integrated circuits, displays, thin-film magnetic pickup heads, and micromachines. More specifically, the disclosure pertains to stencil reticles for use in microlithography performed using a charged particle beam, and to methods for fabricating such reticles.

### BACKGROUND

Most conventional microlithography technology remains “optical” in nature, chiefly utilizing deep UV wavelengths of light. Even though optical microlithography has been developed to exhibit extremely high performance, optical microlithography has limits with respect to the maximum achievable resolution of the transferred pattern. Meanwhile, there has been a relentless increase in the integration of active circuit elements in microelectronic devices, which has urged the development of “next-generation” microlithography systems that use an energy beam other than deep UV light to achieve substantially finer resolution than obtainable using optical microlithography. Promising candidate next-generation microlithography technologies utilize a charged particle beam (e.g., electron beam or ion beam) or an X-ray beam as the lithographic energy beam. Certain of these next-generation technologies are on the threshold of being “practical.”

As noted above, an exemplary charged-particle-beam (CPB) microlithography apparatus utilizes an electron beam. It now is possible to focus an electron beam to a diameter of a few nanometers. Such a narrow beam advantageously can form pattern features, as projected onto a lithographic substrate, of 0.1 μm or smaller.

Certain conventional electron-beam lithographic exposure systems utilize an electron beam to draw patterns feature-by-feature. With such a system, the finer the pattern, the narrower the beam must be, and the longer the time necessary to draw the pattern. With these systems, low throughput is a major problem.

Consequently, much development effort currently is being expended to provide a practical CPB microlithography system that utilizes a “divided” or “segmented” reticle. A divided reticle defines an entire pattern to be transferred to a substrate, but the pattern as defined on the reticle is divided into a large number of portions (termed “subfields”) each defining a respective portion of the pattern. Typically, each subfield as projected onto the substrate is dimensioned approximately 200-250 μm on each side (wherein a 250-μm square subfield on the substrate is about the largest that can be exposed currently without significant aberration). Since projection normally is performed with demagnification (e.g., 1/5), each subfield is dimensioned approximately 1 mm per side on the reticle.

A representative portion of such a reticle 1 is shown in FIGS. 4(a)-4(b), in which FIG. 4(b) is an oblique perspective view, and FIG. 4(a) is an elevational section along the line A-A. A number of individual subfields SF are shown. In each subfield SF the respective pattern portion is defined in a respective portion of the reticle membrane M. The surface 6 represents a “first major surface” of the reticle 1. Individual subfields SF are separated from one another by intersecting “struts” 2 that collectively form a lattice-like “grillage” conferring substantial structural strength and rigidity to the reticle 1. The edges of the struts 2 collectively define a plane 5 that is parallel to the plane defined by the membrane M. The plane 5 represents a “second major surface” of the reticle 1. The depicted reticle 1 is a “stencil” reticle in which pattern features are defined as corresponding CPB-transmissive through-holes (apertures) 3 in the relatively CPB-scattering reticle membrane M. The membrane M typically is about 2 μm thick. It will be appreciated that a typical divided reticle 1 comprises a large number (typically many thousands) of subfields SF.

The reticle 1 is conventionally fabricated by the following method. A silicon wafer is prepared having parallel major surfaces that are (100) crystal surfaces. A first major surface of a silicon (Si) wafer is boron-doped to a predetermined depth (and boron concentration, usually 1×10²⁰ atoms/cm³) in the thickness dimension of the wafer. The opposing second major surface of the wafer is patterned and masked (with, e.g., silicon oxide) to define the arrangement of the struts 2 (i.e., regions to be occupied by the struts 2 are masked and other regions are left “exposed” to an etchant). The exposed silicon on the second major surface of the wafer is anisotropically wet-etched, into the thickness dimension from the masked second major surface, using an aqueous potassium hydroxide etchant solution. Etching stops when the etchant has penetrated through the thickness dimension of the wafer to the boron-doped layer, thereby leaving the boron-doped layer as the membrane M. Thus, a “reticle blank” is made. Next, a resist or the like is applied to the boron-doped first major surface of the wafer. The resist is imaged with the desired reticle pattern using an electron-beam drawing apparatus. Using the resulting resist pattern as a mask, the reticle membrane M is etched to form the through-holes 3 corresponding to the respective pattern elements.

In the method described above, the wet-etching is anisotropic by crystal plane. Consequently, the struts 2 are formed having side-walls sloped at an angle of 54.74° relative to the plane of the membrane M. These sloped side-walls collectively occupy much space on the reticle, which requires that a reticle defining an entire pattern be very large. Unfortunately, the larger the reticle, the more fragile and more difficult it is to handle and use. Hence, alternative reticle-fabrication methods have been proposed that effectively provide the struts 2 with steeper sidewalls and thus a thinner transverse section. These alternative methods employ dry-etching to form the struts.

An exemplary alternative method is depicted in FIGS. 5(a)-5(c). In the first step, a first major surface of a silicon wafer 14 is doped with boron to form a boron-doped layer 13 (FIG. 5(a)). In a second step, a strut-defining mask 15 (silicon oxide) is applied to the second major surface, and the exposed silicon on the second major surface is dry-etched into the thickness dimension toward the boron-doped layer 13 until a few tens of μm (e.g., 20 to 30 μm) of undoped silicon 16 are left, thereby forming most of the struts 12 (FIG. 5(b)). Next, anisotropic wet-etching is performed to etch away the remaining undoped silicon 16. Wet-etching stops at the boron-doped layer 13, leaving a reticle membrane M having a specified thickness. Note that the wet-etching leaves sloped “feet” on the struts 12. After removing residual material of the mask 15, formation of the reticle blank is complete (FIG. 5(c)). Subsequent patterning of the membrane M completes fabrication of a reticle.

A simplified version of the method of FIGS. 5(a)-5(c) begins with an SOI (Silicon On Insulator) wafer as shown in FIG. 6(a). The SOI wafer includes a silicon oxide layer 17 formed on a silicon substrate 18. A thin silicon layer 19 is formed superposedly on the oxide layer 17. The silicon oxide layer 17 can be used as an etch-stop layer for dry-etching. Thus, beginning with a masked SOI wafer, a reticle blank can be fabricated comprising struts having perpendicular (maximally steep) side walls and individual transverse widths of a few hundred μm. The struts are formed by dry-etching the silicon substrate 18.

FIGS. 6(a)-6(c) are sectional views of the results of respective steps in a method for fabricating a reticle blank beginning with an SOI wafer. First, as shown in FIG. 6(a), an SOI wafer is prepared as described above. Next, as shown in FIG. 6(b), a durable resist or silicon oxide layer 20 is applied to the “lower” (in the figure) surface of the silicon substrate 18. The resist layer 20 is patterned to mask regions corresponding to the intended locations of the struts 22a-22c (FIG. 6(c)). Next, the silicon substrate 18 is dry-etched according to the mask pattern, with the silicon oxide layer 17 serving as an etch-stop layer. The resulting struts 22a-22a have maximally steep side-walls and are typically a few hundred μm wide in the transverse direction. Next, the exposed silicon oxide layer 17 is etched away (using, e.g., hydrofluoric acid). Removing the residual mask 20 completes fabrication of the reticle blank (FIG. 6(c)).

In both methods described above, etching must be performed to a depth substantially equal to the thickness of the silicon wafer (or silicon substrate). The wafer thickness depends upon wafer diameter. For example, with a 3-inch diameter wafer, the etching depth is approximately 30 μm or greater; with an 8-inch diameter wafer, the etching depth is approximately 700 μm or greater. FIG. 7 depicts an exemplary reticle blank 25 fabricated from an 8-inch diameter wafer. The reticle blank 25 defines two 132 mm×55 mm pattern-defining zones 26a, 26b each comprising a large number of subfields separated from each other by struts, as described above. The zones 26a, 26b are separated from each other by an intervening wide strut 27.

Conventionally, dry-etching to depths of hundreds of μm (e.g., 700 μm or greater) are performed with side-wall protection to ensure accurate unidirectional etching. I.e., for suppressing etching in the lateral direction (e.g., into the side-walls of struts being formed by the etching), the dry-etching is performed in the presence of a polymer-forming gas. As etching proceeds in the thickness dimension of the wafer, the polymer-forming gas reacts to form molecules of the polymer that deposit on the side-walls and protect the side-walls from the etching gas. Thus, the regions between the struts are etched away depthwise while providing the resulting struts with side-walls having good perpendicularity relative to the membrane.

The conventional processes described above are for fabricating reticle blanks; completing formation of the reticle requires dry-etching of the membrane from the first major surface of the reticle blank (i.e., from the planar surface of the membrane). This dry-etching step forms the CPB-transmissive apertures (through-holes) in the membrane to form the pattern on the reticle. Dry-etching is performed on the membrane itself. To avoid problems such as excessive temperature increases of the membrane, etching is repeatedly turned ON and OFF every few minutes or every half-minute as the membrane is being etched.

Another problem has no conventional solution. Namely, during dry-etching of a stencil pattern in the membrane of a reticle blank, after the apertures have penetrated through the membrane, etching gas tends to pass through the apertures and accumulate “behind” the membrane (i.e., in the space between the etching electrode, the struts, and the reticle membrane). This entrapped etching gas undesirably erodes the “back side” of the membrane (i.e., the membrane surface adjacent the struts). The erosion makes the back side of the membrane rough and/or causes membrane fracture. This problem is especially prevalent when forming stencil patterns having a high density of pattern elements and/or patterns in which the smallest features have dimensions of 0.5 μm or less.

### SUMMARY

In view of the disadvantages of conventional methods as summarized above, the invention provides, inter alia, methods for fabricating stencil reticles in which damage to the reticle membrane by entrapped dry-etching gas is substantially reduced compared to conventional reticle fabrication methods. Hence, membrane fracture that otherwise would arise due to the damage is substantially reduced compared to conventional stencil reticles.

To such end, and according to a first aspect of the invention, methods are provided for manufacturing, from a reticle blank, a stencil reticle for use in charged-particle-beam microlithography. In an embodiment of such a method, a reticle blank is prepared that comprises a membrane supported by a grillage of struts separating individual subfields of the membrane from one another. The membrane defines a first major surface of the reticle blank, and the struts define, collectively edgewise, a second major surface of the reticle blank. A layer of resist is formed on the first major surface and patterned according to a desired reticle pattern so as to leave “exposed” areas of the resist corresponding to respective elements of the pattern. The reticle blank is mounted to a major surface of a dry-etching electrode. Using the layer of resist as an etching mask and while supplying a dry-etching gas to the first major surface, the exposed areas are dry-etched to form a reticle pattern of stencil apertures on the membrane. During the dry-etching step, dry-etching gas is exhausted from between the membrane and the dry-etching electrode.

The step of mounting the reticle blank to the dry-etching electrode can comprise providing a defined gap between the second major surface of the reticle blank and the major surface of the dry-etching electrode. The defined gap can be provided by interposing multiple spacer blocks between the second major surface of the reticle blank and the major surface of the dry-etching electrode. The spacer blocks desirably are placed equally spaced around a periphery of the reticle blank.

The method can further include the step of providing the dry-etching electrode configured such that the major surface of the dry-etching electrode defines multiple grooves or channels extending into a thickness dimension of the electrode. With such an electrode, the step of exhausting the dry-etching gas desirably includes drawing the etching gas through the grooves from between the membrane and the dry-etching electrode. The grooves desirably are configured to intersect with each other in a lattice manner. With such a configuration of grooves, the step of mounting the reticle blank to the electrode desirably includes aligning the reticle blank relative to the dry-etching electrode such that intersections of grooves in the major surface of the electrode are situated in respective centers of respective subfields of the reticle blank.

In the method, the step of preparing the reticle blank can comprise providing notches in the struts of the reticle blank. The notches desirably extend from the second major surface of the reticle blank partially depthwise toward the first major surface of the reticle blank. With such a reticle-blank configuration, the step of exhausting the etching gas desirably comprises drawing the etching gas through passageways defined by the notches whenever the second major surface of the reticle blank is in contact with the major surface of the dry-etching electrode.

The step of preparing the reticle blank alternatively can comprise configuring the struts of the reticle blank such that, whenever the second major surface is in contact with the major surface of the dry-etching electrode, passageways are defined collectively by the struts through which etching gas is exhausted during the exhausting step.

According to another method embodiment, a reticle blank is prepared that comprises a membrane supported by a grillage formed from a silicon substrate. The membrane defines a first major surface of the reticle blank, and the grillage defines: (1) collectively edgewise, a second major surface of the reticle blank, and (2) a plurality of notches extending from the second major surface partially depthwise toward the first major surface. A resist pattern is formed on the first major surface. The second major surface of the reticle blank is mounted to a major surface of a dry-etching electrode. The reticle blank, while mounted to the electrode, is exposed to a dry-etching gas so as to dry-etch the resist pattern to form a corresponding pattern of stencil apertures extending depthwise through a thickness dimension of the membrane. While dry-etching the resist pattern, dry-etching gas is exhausted from between the membrane and the dry-etching electrode by drawing the gas through passageways defined by the notches whenever the second major surface of the reticle blank is in contact the major surface of the dry-etching electrode.

In the foregoing method embodiment, the preparing step can comprise forming the grillage by dry-etching the silicon substrate. Alternatively, the preparing step can comprise forming the grillage first by electric-discharge machining to form at least the notches, then by dry-etching the silicon substrate to complete forming the grillage.

According to another aspect of the invention, stencil reticles are provided for use in CPB microlithography. An embodiment of such a stencil reticle comprises a reticle membrane defining a pattern of stencil apertures extending through a thickness dimension of the membrane, wherein the membrane defines a first major surface of the reticle. The reticle also comprises a grillage of struts supporting the membrane and separating individual subfields of the reticle from one another. The struts define, collectively edgewise, a second major surface of the reticle. The reticle also includes a plurality of notches defined in the struts and extending from the second major surface partially depthwise toward the first major surface.

According to another aspect of the invention, stencil reticles are provided that are fabricated according to any of the above-summarized method embodiments.

The foregoing and additional features and advantages of the invention will be more readily apparent from the following detailed description, which proceeds with reference to the accompanying drawings.

### BRIEF DESCRIPTION OF THE DRAWINGS

FIGS. 1(a) and 1(b) are a plan view and elevational (with partial section) view, respectively, of a reticle blank attached to an etching electrode in a method, according to a first representative embodiment, for fabricating a stencil reticle from a reticle blank.

FIG. 2(a) is a plan view of a lower etching electrode used in a method, according to the second representative embodiment, for fabricating a stencil reticle from a reticle blank.

FIG. 2(b) is an oblique perspective view of a portion of the electrode shown in FIG. 2(a).

FIG. 3 is an oblique perspective view of a portion of a reticle blank, showing the configuration of reticle struts, as used in a method, according to the third representative embodiment, for fabricating a stencil reticle from a reticle blank.

FIG. 4(a) is an elevational section (along the line A-A in FIG. 4(b)) of a portion of a conventional segmented stencil reticle as used for performing charged-particle-beam (CPB) microlithography.

FIG. 4(b) is an oblique perspective view of the portion of a segmented reticle shown in FIG. 4(a), depicting multiple subfields separated from each other by a grillage of struts and each subfield having a respective portion of the reticle membrane defining a respective portion of the reticle pattern.

FIGS. 5(a)-5(c) are elevational sections showing the results of respective steps in a first conventional method for fabricating a reticle blank used for fabricating a stencil reticle for use in CPB mricrolithography.

FIGS. 6(a)-6(c) are elevational sections showing the results of respective steps in a second conventional method for fabricating a reticle blank, starting with an SOI wafer (FIG. 6(a)).

FIG. 7 is a plan view of a reticle blank fabricated from an 8-inch diameter wafer.

### DETAILED DESCRIPTION

The following description is set forth in the context of representative embodiments that are not intended to be limiting in any way.

First Representative Embodiment

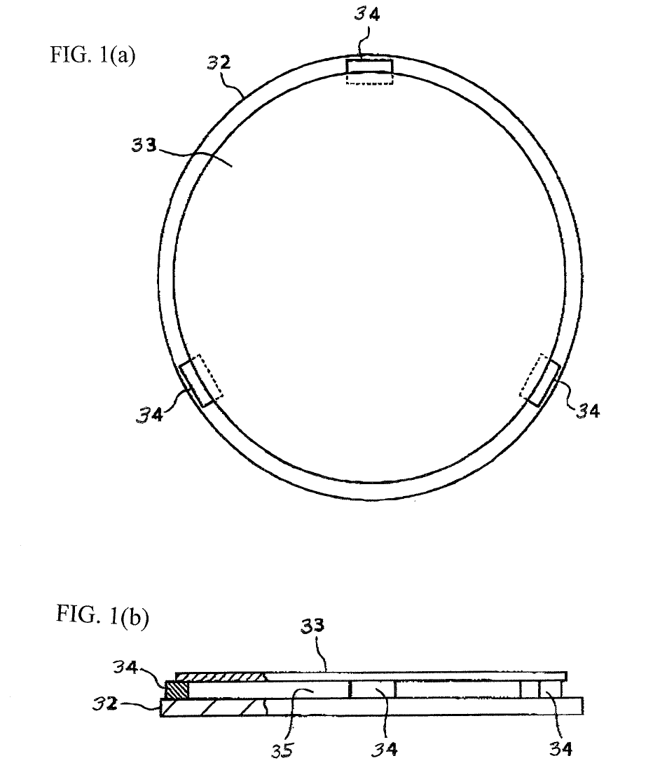

A method, according to this embodiment, for fabricating a stencil reticle for use in electron-beam microlithography (as an exemplary charged-particle-beam microlithography) is depicted in FIGS. 1(a)-1(b). FIG. 1(a) is a plan view, and FIG. 1(b) is an elevational (and partial sectional) view.

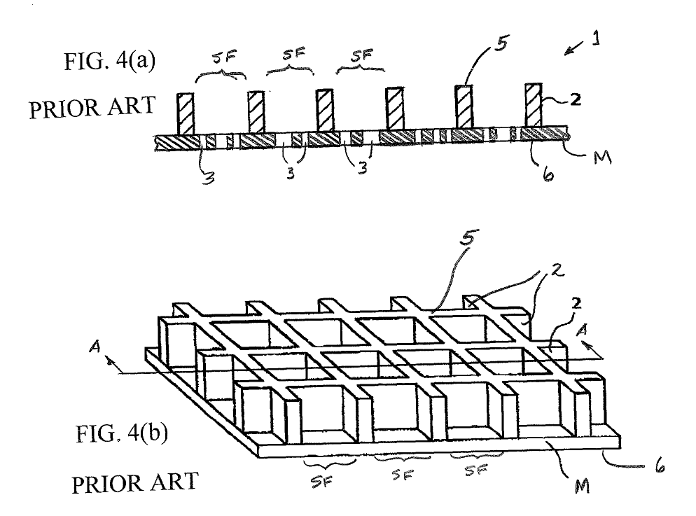

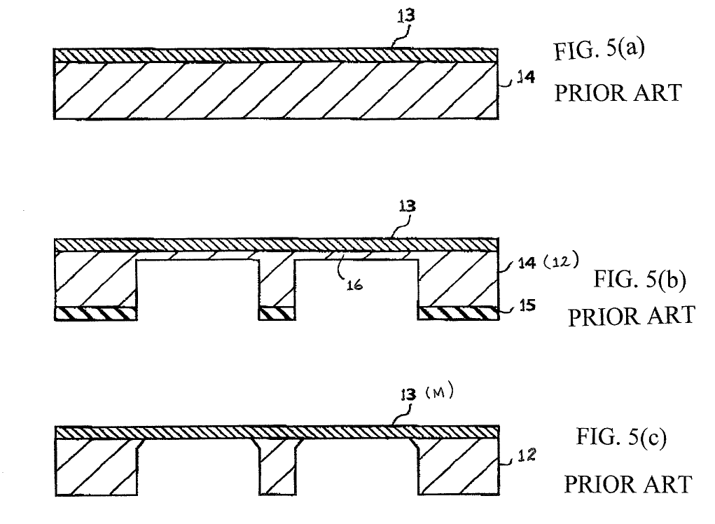

First, a reticle blank 1 such as that shown in FIGS. 4(a)-4(b) is fabricated. The reticle blank 1 has a “first” major surface 6 (i.e., the planar surface of the membrane M, which is opposite the “second” major surface 5 collectively defined by the edges of the struts 2). The membrane M is made of an electron-scattering silicon material and is approximately 2 μm thick. The grillage of struts 2 is made from a silicon substrate as summarized above.

A suitable resist is applied to the first major surface 6. The resist is lithographically exposed to imprint a desired reticle pattern in the resist. The imprinted pattern is the pattern of through-holes (electron-transmissive apertures) that, together with the intervening regions of membrane M, define the elements of the reticle pattern. The developed resist serves as an etching mask in the next step.

Next, the membrane M is dry-etched according to resist pattern to form the apertures in the membrane. The manner in which this dry-etching step is performed is described below.

Turning first to FIG. 1(a), a reticle blank 33 is shown. The reticle blank 33 includes a membrane coated with a dry-etching mask formed as described above. The dry-etching mask defines the desired pattern of through-holes to be formed in the membrane. For placement inside a chamber of a dry-etching apparatus, the reticle blank 33 is mounted on a “lower” etching electrode 32. When mounting the reticle blank 33 to the etching electrode 32, the reticle blank 33 is displaced from the etching electrode, desirably at three peripheral locations on the reticle blank, by spacer blocks 34. The spacer blocks each have a “height” of 30 μm or greater, thereby forming a gap 35 of 30 μm or greater between the reticle blank 33 and the etching electrode 32. Thus, during dry-etching of the membrane of the reticle blank 33, as the outer periphery of the reticle blank rests on the spacer blocks 34 (FIG. 1(b)), the first major surface (i.e., the masked planar surface of the membrane, facing upward in FIG. 1(b)) is impinged by the dry-etching.

The assembly shown in FIGS. 1(a)-1(b) is placed inside an etching chamber (not shown), and a suitable dry-etching gas is discharged into the chamber. Energization of the electrodes (including the electrode 32) in the chamber generates a plasma in the chamber. The plasma ionizes molecules of the gas, and the ions move toward and collide substantially perpendicularly with the first major surface of the reticle blank 33. The collisions of energetic ions with the “exposed” (non-masked) regions of the membrane surface causes etching away of membrane material, according to the mask pattern, into the thickness dimension of the membrane. Etching is continued until the electron-transmissive apertures have been formed in the membrane.

By mounting the reticle blank 33 to the etching electrode 32 in the manner described above, dry-etching gas that has passed through the apertures in the membrane and that has accumulated “behind” the membrane is readily exhausted from the gap 35. By thus rapidly exhausting the gas, the gas does not accumulate in the spaces between the membrane, the etching electrode 32, and the struts, thereby preventing undesired erosion of the “back” of the membrane. By preventing this erosion, the incidence of membrane fracture is substantially reduced.

Second Representative Embodiment

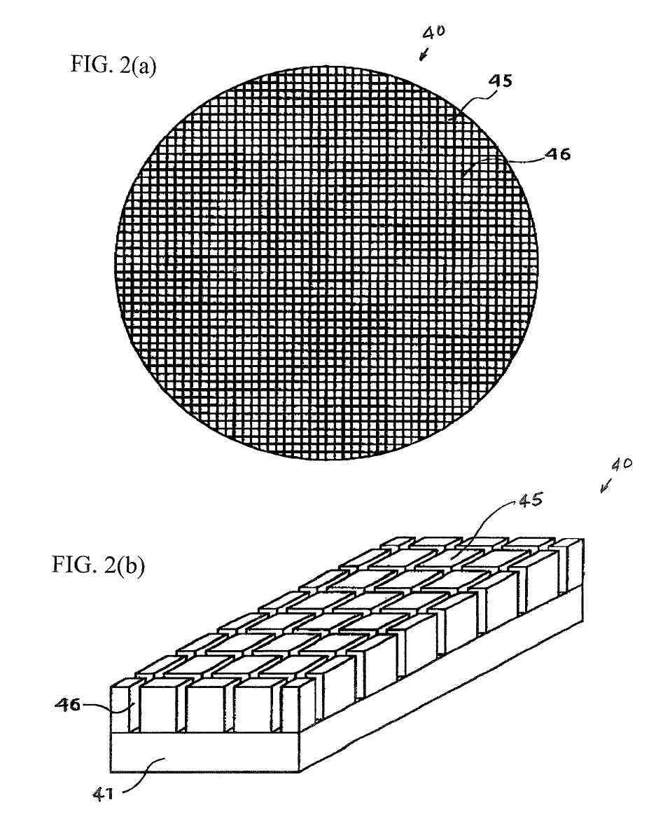

A method, according to this embodiment, for fabricating a stencil reticle for use in electron-beam microlithography (as an exemplary charged-particle-beam microlithography) is depicted in FIGS. 2(a)-2(b). FIG. 2(a) is a plan view of the lower dry-etching electrode used in the method, and FIG. 2(b) is an oblique perspective view of an enlarged portion of the electrode. Portions of the method that are the same as in the first representative embodiment are not described further.

A reticle blank (see FIGS. 4(a)-4(b)) is prepared as described above. The first major surface 6 (planar membrane surface) of the reticle blank 1 is patterned and masked, in the manner described above, according to the desired stencil pattern to be formed in the membrane M. Then the reticle blank 1 is dry-etched, according to the mask pattern, using a lower etching electrode as described below.

Turning first to FIG. 2(a), the etching electrode 40 has a major surface 45 in which multiple grooves or channels 46 are defined in two dimensions. The grooves 46 are configured desirably orthogonally so as to mutually intersect each other at right angles. The grooves 46 do not extend depthwise completely through the thickness dimension of the electrode 40, thereby leaving a base portion 41. The major surface 45 serves as the mounting surface for the reticle blank 1. As can be discerned from comparing FIG. 2(b) with FIG. 4(b), the grooves 46 are lattice-like in configuration and desirably have the same pitch as the grillage of struts 2. A reticle blank 1 as shown in FIG. 4(b) is placed on the etching electrode 40 such that the major surface 5 in FIG. 4(b) (i.e., the surface collectively defined by the edges of the struts 2) contacts the upward-facing major surface 45 in FIG. 2(b). Desirably, the reticle blank 1 is positioned on the major surface 45 such that the intersection of each pair of grooves 46 is situated over the middle of a respective subfield SF, i.e., midway in the space between respective pairs of struts 2 on the reticle blank.

The masked reticle blank 1 is mounted to the major surface 45 of the etching electrode 40, as described above, without having to use the spacer blocks 34 employed in the first representative embodiment. The spacer blocks 34 are not required in this second representative embodiment because the grooves 46 in the major surface 45 provide conduits for the rapid removal of etching gas from the spaces between the etching electrode, the reticle membrane, and the reticle struts.

The masked reticle blank 1 mounted to the etching electrode 40 as described above is placed in the chamber of a dry-etching apparatus. Etching gas is discharged into the chamber while the etching electrode is electrically energized, which generates a plasma in the chamber. The plasma ionizes molecules of the etching gas, and the ions collide substantially perpendicularly with the first major surface 6 of the reticle blank. The resulting collision of the ions with unmasked regions of the membrane etches the unmasked regions into the thickness dimension of the membrane. Dry-etching is continued until the pattern-defining apertures have been etched through the thickness dimension of the membrane, thereby forming a stencil reticle for use in electron-beam microlithography.

After the apertures have been completely etched depthwise through the thickness dimension of the membrane, etching gas can penetrate through the apertures to the “back” of the reticle membrane. However, rather than remaining trapped behind the membrane, the etching gas is exhausted readily through the grooves 46 defined in the etching electrode 40. This rapid exhaustion of etching gas prevents erosion of the back of the membrane, and thus prevents membrane fracture.

Third Representative Embodiment

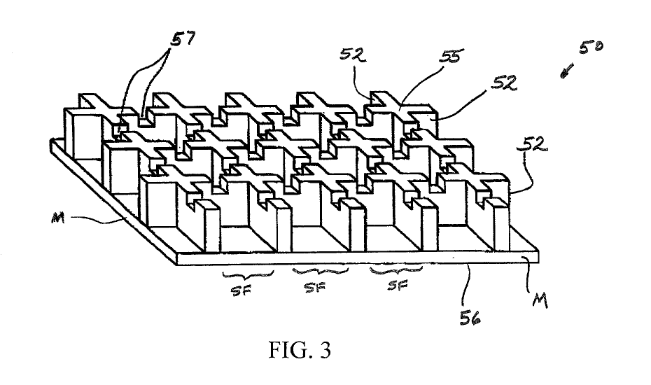

Dry-etching of a reticle blank 50 (FIG. 3), according to this embodiment, is performed using a conventional etching electrode. However, the second major surface 55 (collectively defined by the edges of the struts 52) of the reticle blank 50 is configured in the manner shown in FIG. 3. FIG. 3 is an oblique perspective view of an enlarged portion of the strut side of the reticle blank. Aspects of this embodiment that are the same as in the first and second representative embodiments are not described further.

Referring further to FIG. 3, the reticle blank 50 comprises a silicon membrane M having a planar first major surface 56 and a grillage of struts 52 formed from a silicon substrate. The first major surface 56 is patterned with a mask to define features of reticle pattern to be formed as corresponding stencil apertures in the membrane M. The struts 52 are similar to the struts 2 shown in FIG. 4(b), except that certain regions on the edges of the struts 52 in FIG. 3 define notches 57. Representative notch dimensions are “height” (i.e., dimension in the depth dimension of the reticle blank) 30 μm and “width” (in the length dimension of the respective strut) 30 μm. Whenever the second major surface 55 (collectively defined by the edges of the struts 52) is in contact with the major surface of an etching electrode during dry-etching, the notches 57 provide conduits through which etching gas can be exhausted from the “back” side of the membrane M.

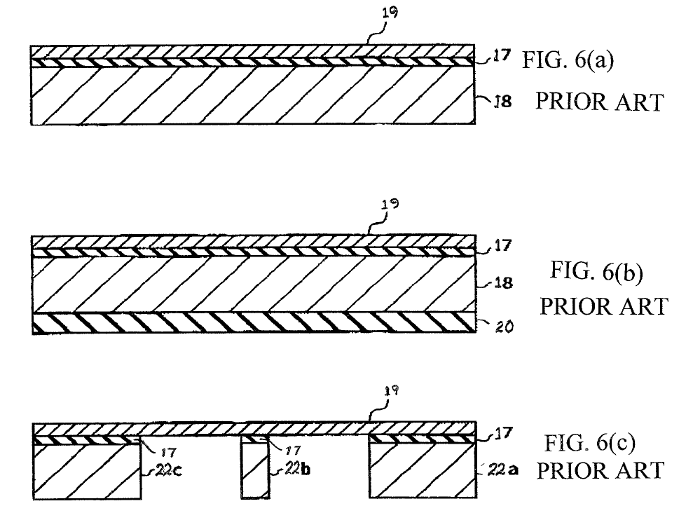

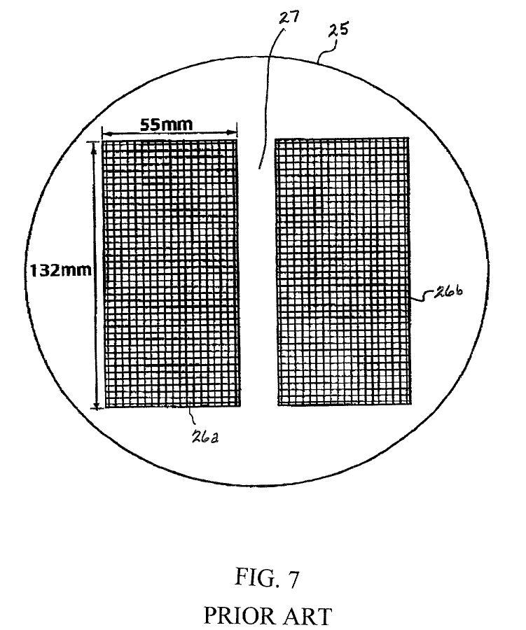

The reticle blank 50 desirably is fabricated by the following method. First, an SOI (Silicon On Insulator) wafer is prepared that comprises a thin silicon layer, a silicon oxide layer, and a silicon substrate (see FIG. 6(a), for example). To form the grillage of struts 52 in the silicon substrate, the spaces between the struts 52 are machined partly away by electric-discharge machining performed using a discharge-machining electrode. The discharge-machining electrode has a planar surface in which grooves are defined that correspond in respective dimensions, positions, and arrangement to the desired respective dimensions, positions, and arrangement of the struts 52. The surface of the electrode also defines ridges that correspond in respective dimensions and positions to the desired respective dimensions and positions of the notches 57. After discharge-machining the silicon substrate to the desired depth (including formation of the notches), the SOI wafer is cleaned, and the remaining silicon substrate is dry-etched down to the silicon oxide layer (which serves as an etch-stop). The “exposed” regions of the silicon oxide layer are removed to complete fabrication of the reticle blank. The resulting reticle blank has a silicon membrane M supported by the notched struts 52.

A film of resist is applied to the surface 56 of the membrane M. The resist is lithographically exposed to define a desired reticle pattern on the surface 56. The resist pattern defines the respective locations of pattern-element-defining stencil apertures to be formed in the membrane M. The resulting masked reticle blank is mounted to a conventional dry-etching lower electrode. Specifically, the reticle blank is placed such that the second major surface 55 contacts the major surface of the electrode. The electrode, with reticle blank mounted thereto, is placed in a dry-etching chamber. While energizing the electrode (to form a plasma), a dry-etching gas is discharged into the chamber. The resulting ions of the etching gas impinging on the surface 56 are allowed to etch through the thickness dimension of the membrane M, according to the mask on the surface 56. At completion of etching, at which time the desired pattern of electron-transmissive stencil apertures has been formed in the membrane, the etching gas is exhausted from behind the membrane through the openings, defined by the notches 57, between the surface 55 and the surface of the electrode. Consequently, erosion of the back side of the membrane M is prevented, with a corresponding reduction in membrane fracture.

It will be understood that any of various modifications can be made to any of the embodiments described above. For example, in the second representative embodiment the grooves 46 in the major surface 45 of the lower etching electrode 40 form a network of intersecting channels desirably having the same pitch as the grillage on the reticle blank. However, the network of grooves is not necessarily so limited. Any of the pitch, depth, and dimensions of the grooves can be suitably modified,

By way of another example, in the third representative embodiment the notches 57 desirably are formed in the centers of the edges of the struts 52 associated with each subfield SF. However, the positions of the notches 57 are not necessarily so limited. The notches alternatively can be formed in any of various other locations on the struts 52. Also, in the third representative embodiment the notches 57 in the struts 52 were formed in part by discharge-machining of the silicon substrate portion of an SOI wafer. Alternatively, the notched struts can be formed in the support silicon solely by etching the silicon substrate portion of an SOI wafer.

In any event, the invention provides, inter alia, any of various ways in which etching gas present behind the reticle membrane can be readily “exhausted” (removed) during and/or after dry-etching of the reticle pattern into the membrane. Thus, stencil reticles can be fabricated without experiencing undesired erosion of the back side of the membrane. The stencil reticles exhibit substantially lower incidence of membrane fracture than conventionally.

Whereas the invention has been described in the context of multiple representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. A method for manufacturing, from a reticle blank, a stencil reticle for use in charged-particle-beam microlithography, the method comprising:
preparing a reticle blank comprising a membrane supported by a grillage of struts separating individual subfields of the membrane from one another, the membrane defining a first major surface of the reticle blank and the struts defining, collectively edgewise, a second major surface of the reticle blank;
forming a layer of resist on the first major surface, the layer of resist being patterned according to a desired reticle pattern so as to leave exposed areas of the resist corresponding to respective elements of the pattern;
mounting the reticle blank to a major surface of a dry-etching electrode;
using the layer of resist as an etching mask and while supplying a dry-etching gas to the first major surface, dry-etching the exposed areas to form a reticle pattern of stencil apertures on the membrane; and
during the dry-etching step, exhausting dry-etching gas from between the membrane and the dry-etching electrode.

2. The method of claim 1, wherein, in the preparing step, the grillage of struts is formed from a silicon substrate.

3. The method of claim 1, wherein, in the preparing step, the membrane is formed from a material comprising silicon.

4. The method of claim 1, wherein:
in the preparing step the reticle blank is prepared from an SOI wafer comprising a silicon substrate; and
the grillage of struts is formed from the silicon substrate.

5. The method of claim 1, wherein the mounting step comprises providing a defined gap between the second major surface of the reticle blank and the major surface of the dry-etching electrode.

6. The method of claim 5, wherein the defined gap is provided by interposing multiple spacer blocks between the second major surface of the reticle blank and the major surface of the dry-etching electrode.

7. The method of claim 6, wherein the spacer blocks are placed equally spaced around a periphery of the reticle blank.

8. The method of claim 1, further comprising the step of providing the dry-etching electrode configured such that the major surface of the dry-etching electrode defines multiple grooves extending into a thickness dimension of the dry-etching electrode.

9. The method of claim 8, wherein the exhausting step comprises drawing the etching gas through the grooves from between the membrane and the dry-etching electrode.

10. The method of claim 8, wherein:
the grooves are configured to intersect with each other in a lattice manner; and
the mounting step comprises aligning the reticle blank relative to the dry-etching electrode such that intersections of grooves in the major surface of the dry-etching electrode are situated in respective centers of respective subfields of the reticle blank.

11. The method of claim 1, wherein the preparing step comprises providing notches in the struts of the reticle blank, the notches extending from the second major surface of the reticle blank partially depthwise toward the first major surface of the reticle blank.

12. The method of claim 11, wherein the exhausting step comprises drawing the etching gas through passageways defined by the notches as the second major surface of the reticle blank contacts the major surface of the dry-etching electrode.

13. The method of claim 1, wherein the preparing step comprises configuring the struts of the reticle blank such that, whenever the second major surface of the reticle blank is in contact with the major surface of the dry-etching electrode, passageways are defined collectively by the struts through which etching gas is exhausted during the exhausting step.

14. A stencil reticle for use in charged-particle-beam microlithography, the stencil reticle comprising:
a reticle membrane defining a pattern of stencil apertures extending through a thickness dimension of the membrane, the membrane defining a first major surface of the reticle;
a grillage of struts supporting the membrane and separating individual subfields of the reticle from one another, the struts defining, collectively edgewise, a second major surface of the reticle; and
a plurality of notches defined in the struts and extending from the second major surface partially depthwise toward the first major surface.

15. A stencil reticle fabricated by the method recited in claim 1.

16. A method for fabricating a stencil reticle for use in charged-particle-beam microlithography, the method comprising:
preparing a reticle blank comprising a membrane supported by a grillage formed from a silicon substrate, the membrane defining a first major surface of the reticle blank, and the grillage defining (1) collectively edgewise, a second major surface of the reticle blank, and (2) a plurality of notches extending from the second major surface partially depthwise toward the first major surface;
forming a resist pattern on the first major surface;
mounting the second major surface of the reticle blank to a major surface of a dry-etching electrode;
exposing the reticle blank, while mounted to the electrode, to a dry-etching gas so as to dry-etch the resist pattern to form a corresponding pattern of stencil apertures extending depthwise through a thickness dimension of the membrane; and
while dry-etching the resist pattern, exhausting dry-etching gas, from between the membrane and the dry-etching electrode by drawing the gas through passageways defined by the notches as the second major surface of the reticle blank contacts the major surface of the dry-etching electrode.

17. The method of claim 16, wherein, in the preparing step, the membrane is formed from a material comprising silicon.

18. The method of claim 16, wherein the preparing step comprises forming the grillage by dry-etching the support silicon.

19. The method of claim 16, wherein the preparing step comprises forming the grillage first by electric-discharge machining to form at least the notches, then by dry-etching the support silicon to complete forming the grillage.

20. A stencil reticle fabricated by the method recited in claim 16.
